(19) United States
(12) Patent Application Publication
(10) Pub. No.: US 2007/0145466 A1
(43) Pub. Date: Jun. 28, 2007

(54) Flash memory device and method for manufacturing the same

(75) Inventor: Young Ho Yang, Cheongju-si (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Kyoungki-do (KR)

(21) Appl. No.: 11/498,389

(22) Filed: Aug. 3, 2006

(30) Foreign Application Priority Data
Dec. 28, 2005 (JP) 2005-131323

(51) Int. Cl. H01L 29/788

(52) U.S. Cl. 257/315

(57) ABSTRACT

A flash memory device and a method of manufacturing the same, wherein a silicon layer having a micro grain is formed between a tunnel oxide layer and a floating gate using a hemi-spherical grain (HSG) method, thereby preventing the dopant of the floating gate from being diffused into the tunnel oxide layer. According to one embodiment, the flash memory device includes isolation structures formed in predetermined regions of a semiconductor substrate, for defining an active region and a field region, a tunnel oxide layer formed on the semiconductor substrate of the active region, and a floating gate formed in a predetermined region on the active region to overlap with a part of the isolation structure, an underlying given portion and the remaining portions of the floating gate having different grain sizes.

### BACKGROUND OF THE INVENTION

The invention relates generally to a flash memory device and a method of manufacturing the same. More particularly, the invention relates to a flash memory device and a method of manufacturing the same, in which a silicon layer having a micro grain is formed between a tunnel oxide layer and a floating gate using a hemi-spherical grain (HSG) method, thereby preventing the dopant of the floating gate from being diffused into the tunnel oxide layer.

A memory device, e.g. a NAND flash memory device, includes a plurality of cell blocks. One cell block includes a plurality of cell strings in which a plurality of cells for storing data are in series connected to form one string, and a drain select transistor and a source select transistor formed between the cell string and the drain, and the cell string and the source, respectively. An exemplary method of fabricating the NAND flash memory cell is described below.

A buffer oxide layer and a pad nitride layer are sequentially formed on a semiconductor substrate in which predetermined structures including a well region, etc., are formed. Predetermined regions of the pad nitride layer and the tunnel oxide layer are etched by photolithography and etch processes using an isolation mask. The semiconductor substrate is etched at a predetermined depth, forming a trench. An insulating layer, such as a high density plasma (HDP) oxide layer, is formed on the entire structure so that the trench is buried. The insulating layer is polished by a chemical mechanical polishing (CMP) process. The pad nitride layer and the pad oxide layer are stripped to form an isolation structure. After a tunnel oxide layer and a first polysilicon layer are formed on the semiconductor substrate, the first polysilicon layer is patterned such that it partially overlaps the isolation structure. A dielectric layer, a second polysilicon layer, and a metal layer are formed on the entire structure. The metal layer is patterned to form a control gate crossing the isolation structure. The underlying first polysilicon layer is etched using the control gate as a mask, thereby forming a floating gate.

In the manufacture process of the NAND flash memory cell as described above, the first polysilicon layer used as the floating gate employs a doped polysilicon layer into which an impurity of a high concentration is doped is used. While the process is performed, however, the dopant of the floating gate diffuses into the interface of the tunnel oxide layer and the floating gate. The dopant degrades the layer quality of the tunnel oxide layer while being accumulated at the interface of the tunnel oxide layer. Accordingly, a problem arises because the data storage and retention capabilities are degraded.

### SUMMARY OF THE INVENTION

One embodiment provides a flash memory device and a method of manufacturing the same, wherein degradation of the layer quality of a tunnel oxide layer due to the diffusion of the dopant of a floating gate into a tunnel oxide layer and a degraded data storage ability accordingly can be prevented.

Another embodiment provides a flash memory device and a method of manufacturing the same, wherein a silicon layer having a micro grain is formed between the tunnel oxide layer and the floating gate using a Hemi-Spherical Grain (HSG) method, thereby preventing the dopant of the floating gate from being diffused into the tunnel oxide layer and making uniform data distributions of each cell.

According to one aspect, the embodiment provides a flash memory device, including isolation structures formed in regions of a semiconductor substrate, to define an active region and a field region, a tunnel oxide layer formed over the semiconductor substrate of the active region, and a floating gate has a grain size smaller in an underlying given portion than in remaining portions.

The floating gate may preferably have the grain size smaller in the underlying given portion than in the remaining portions. The floating gate may preferably have in a predetermined region on the active region to overlap with a part of the isolation structure, the underlying given portion and the remaining portions of the floating gate having different grain sizes.

According to another aspect, the invention provides a method of manufacturing a flash memory device, including the steps of forming isolation structures in a semiconductor substrate to define an active region and a field region, forming a tunnel oxide layer over the semiconductor substrate of the active region; and forming a conductive layer over the tunnel oxide layer, an underlying given portion and the remaining portions of the conductive layer having different grain sizes.

According to another, further aspect, the invention provides a method of manufacturing a flash memory device, including the steps of forming isolation structures in a semiconductor substrate to define an active region and a field region; forming a tunnel oxide layer over the semiconductor substrate of the active region; forming a silicon layer having a micro grain over the tunnel oxide layer and then forming a polysilicon layer, and patterning the polysilicon layer and the silicon layer.

The polysilicon layer and the silicon layer may preferably be partially overlapped with the isolation structure and are parallel to the isolation structure.

The tunnel oxide layer may preferably be formed to a thickness of 50 Å to 100 Å by oxidizing the semiconductor substrate using a mixed gas of oxygen and hydrogen.

The method may further include the step of performing a hot anneal process at a temperature of 850° C. to 950° C. under in-situ or ex-situ NO or N₂O atmosphere after the tunnel oxide layer is formed.

The silicon layer having the micro grain may preferably be formed by forming an amorphous silicon layer on the entire structure and then performing an anneal process at a high temperature under low pressure conditions so that atoms of the amorphous silicon layer are combined together.

The amorphous silicon layer may preferably be formed to a thickness of 50 Å to 300 Å using a source gas such as SiH₄ or SiH₂Cl₂, for example.

The anneal process may preferably be performed at a temperature of 600° C. to 750° C. under ultra-vacuum state of 1E-5 torr to 1E-8 torr.

During the annealing process, a silicon source gas of about 1 sccm to 50 sccm may preferably be injected in order to maintain the size of the micro grain to 50 Å to 500 Å.

The polysilicon layer may preferably be formed by doping boron or phosphorous of 1.0e19 atoms/cm³ to 5.0e21 atoms/cm³ in-situ at a temperature of 450° C. to 650° C.

The method may further optionally include the steps of forming a dielectric layer on the entire structure and then forming a conductive layer; and patterning the conductive layer in such a way to cross the isolation structures, thus forming a control gate, and then patterning the polysilicon layer and the silicon layer having the micro grain, thus forming a floating gate.

The method may further optionally include the step of performing annealing and oxidization using a mixed gas of oxygen and hydrogen at a temperature of 600° C. to 900° C., for example, after the dielectric layer is formed.

### BRIEF DESCRIPTION OF THE DRAWINGS

A more compete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIGS. 1A to 1E are cross-sectional views illustrating a method of manufacturing a flash memory device according to an embodiment of the invention.

### DETAILED DESCRIPTION OF EMBODIMENTS

The invention is described in detail in connection with certain exemplary embodiments with reference to the accompanying drawings.

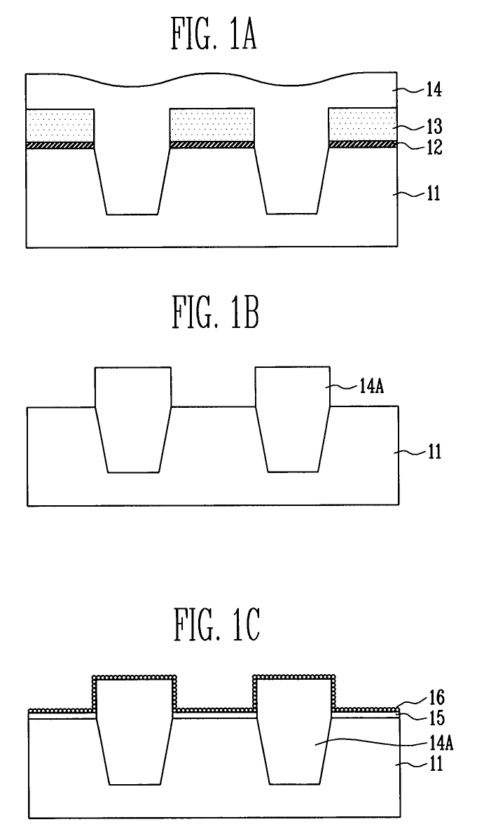

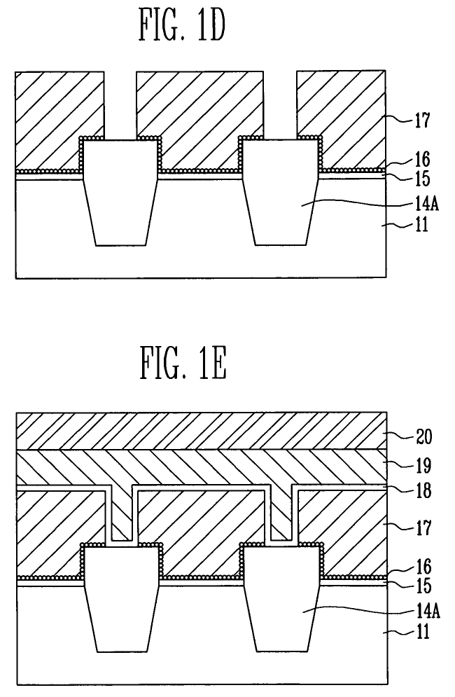

FIGS. 1A to 1E are cross-sectional views illustrating a method of manufacturing a flash memory device according to an embodiment of the invention.

Referring to FIG. 1A, a pad oxide layer 12 and a pad nitride layer 13 are sequentially formed on a semiconductor substrate 11. Predetermined regions of the pad nitride layer 13 and the pad oxide layer 12 are etched by photolithography and etch processes using an isolation mask. The semiconductor substrate 11 is then etched at a predetermined depth, forming trenches. An oxide layer 14 is formed on the entire structure so that the trench is buried.

Referring to FIG. 1B, the oxide layer 14 is polished so that the pad nitride layer 13 is exposed. The pad nitride layer 13 and the pad oxide layer 12 are then stripped. Accordingly, isolation structures 14A defining an active region and a field region are formed in a field region. The pad nitride layer 13 may be wet etched using H₃PO₄ and the pad oxide layer 12 may be wet etched using a HF-based solution, for example.

Referring to FIG. 1C, a tunnel oxide layer 15 is formed the semiconductor substrate 11 of the active region. The tunnel oxide layer 15 is preferably formed to a thickness of 50 Å to 100 Å by oxidizing the semiconductor substrate 11 using a mixed gas of oxygen and hydrogen. Furthermore, a hot anneal process is preferably performed at a temperature of 850° C. to 950° C. under in-situ or ex-situ NO or N₂O atmosphere in order to control the tunneling effect of hot electrons.

A silicon layer 16 having a micro grain are formed on the entire structure, preferably using the HSG method. In the HSG method, after an amorphous silicon layer of about 50 Å to 300 Å in thickness is formed using a source gas such as SiH₄ or SiH₂Cl₂, an anneal process is performed at a high temperature under low pressure conditions so that silicon atoms of the amorphous silicon layer are combined together, forming the silicon layer 16 having a micro grain. At this time, the anneal process may be performed, preferably at a temperature of 600° C. to 750° C. under an ultra-vacuum state of 1E-5 torr to 1E-8 torr. To form the nucleus of the micro grain, the silicon source gas of about 1 sccm to 50 sccm is injected so that the size of the micro grain is kept to 50 Å to 500 Å.

Referring to FIG. 1D, a first polysilicon layer 17 is formed on the entire structure including the silicon layer 16 having the micro grain. At this time, an amorphous silicon layer may be formed instead of the first polysilicon layer 17. The amorphous silicon layer or the first polysilicon layer may be formed by doping boron or phosphor of 1.0e19 atoms/cm³ to 5.0e21 atoms/cm³ in-situ at a temperature of 450° C. to 650° C., for example.

Thereafter, predetermined regions of the first polysilicon layer 17 and the silicon layer 16 are etched so that a predetermined region of the isolation structure 14A is exposed.

Referring to FIG. 1E, a dielectric layer 18 having an oxide layer, a nitride layer, and an oxide layer is formed on the entire structure. A second polysilicon layer 19 and a metal layer 20 are then sequentially formed on the dielectric layer 18. The oxide layer and the nitride layer of the dielectric layer 18 may be formed using a mixed gas of N₂O, NH₃, etc. and a source gas, such as SiH₄ or SiH₂Cl₂, using low pressure chemical vapor deposition (LPCVD) or atomic layer deposition (ALD). The oxide layer may preferably be formed at a temperature of 780° C. to 850° C. and the nitride layer may preferably be formed at a temperature of 600° C. to 750° C.

After the dielectric layer 18 is formed, annealing and oxidization are performed, preferably using a mixed gas of oxygen and hydrogen at a temperature of 600° C. to 900° C. The second polysilicon layer 19 and the metal layer 20 are then patterned to form a control gate of a line shape, which crosses the isolation structure 14A. The underlying dielectric layer 18, the second polysilicon layer 17, and the silicon layer 16 are etched to form a floating gate.

Meanwhile, the silicon layer having the micro grain, which is preferably formed by the HPG method, may be formed between the tunnel oxide layer and the floating gate in order to prevent the dopant of the floating gate from diffusing into the tunnel oxide layer by using any method in the process of manufacturing the flash memory device, which forms the isolation structure and the floating gate by a general shallow trench isolation (STI) method, a self-aligned (SA) STI method or a self-aligned floating gate (SAFG) method.

As described above, according to the invention, the silicon layer having a micro grain is formed between the floating gate and the tunnel oxide layer by the HSG method. The dopant of the floating gate can be prevented from diffusing into the tunnel oxide layer. Accordingly, the tunnel oxide layer can be prevented from being degraded, the data storage and retention capabilities can be maintained stably, and data distributions of each cell can be made uniform.

While the invention has been described in connection with practical exemplary embodiments the invention is not limited to the disclosed embodiments but, to the contrary, is intended to cover various modifications and equivalent arrangements included within the spirit and scope of the appended claims.

What is claimed is:

1. A flash memory device comprising:
isolation structures formed in regions of a semiconductor substrate, to define an active region and a field region;
a tunnel oxide layer formed over the semiconductor substrate of the active region; and
a floating gate has a grain size smaller in an underlying given portion than in remaining portions.

2. The flash memory device of claim 1, wherein the floating gate formed in a predetermined region on the active region to overlap with a part of the isolation structure, the underlying given portion and the remaining portions of the floating gate having different grain sizes.

3. A method of manufacturing a flash memory device, comprising the steps of:
forming isolation structures in a semiconductor substrate to define an active region and a field region;
forming a tunnel oxide layer over the semiconductor substrate of the active region; and
forming a conductive layer over the tunnel oxide layer, an underlying given portion and the remaining portions of the conductive layer having different grain sizes.

4. A method of manufacturing a flash memory device, comprising the steps of:
forming isolation structures in predetermined regions of a semiconductor substrate to define an active region and a field region;
forming a tunnel oxide layer on the semiconductor substrate of the active region;
forming a silicon layer having a micro grain on the entire structure and then forming a polysilicon layer; and
patterning the polysilicon layer and the silicon layer.

5. The method of claim 4, wherein the polysilicon layer and the silicon layer are partially overlapped with the isolation structure and are parallel to the isolation structure.

6. The method of claim 4, comprising forming the tunnel oxide layer to a thickness of 50 Å to 100 Å by oxidizing the semiconductor substrate using a mixed gas of oxygen and hydrogen.

7. The method of claim 4, further comprising the step of performing a hot anneal process at a temperature of 850° C. to 950° C. under an in-situ or ex-situ NO or N₂O atmosphere after forming the tunnel oxide layer.

8. The method of claim 4, comprising forming the silicon layer having the micro grain by forming an amorphous silicon layer on the entire structure and then performing an anneal process at a high temperature under low pressure conditions so that atoms of the amorphous silicon layer are combined together.

9. The method of claim 8, comprising the amorphous silicon layer is formed to a thickness of 50 Å to 300 Å using a source gas.

10. The method of claim 9, wherein the source gas is SiH₄ or SiH₂Cl₂.

11. The method of claim 8, comprising performing the anneal process at a temperature of 600° C. to 750° C. under an ultra-vacuum state of 1E-5 torr to 1E-8 torr.

12. The method of claim 8, comprising, during the anneal process, injecting a silicon source gas of about 1 sccm to 50 sccm in order to maintain the size of the micro grain to 50 Å to 500 Å.

13. The method of claim 3, comprising forming the polysilicon layer by doping boron or phosphorous of 1.0e19 atoms/cm³ to 5.0e21 atoms/cm³ in-situ at a temperature of 450° C. to 650° C.

14. The method of claim 3, further comprising the steps of:
forming a dielectric layer on the entire structure and then forming a conductive layer; and
patterning the conductive layer in such a way to cross the isolation structures, thus forming a control gate, and then patterning the polysilicon layer and the silicon layer having the micro grain, thus forming a floating gate.

15. The method of claim 14, further comprising the step of performing annealing and oxidization using a mixed gas of oxygen and hydrogen at a temperature of 600° C. to 900° C., after the dielectric layer is formed.
